(19) United States
(12) Patent Application Publication
(10) Pub. No.: US 2015/0200082 A1
(43) Pub. Date: Jul. 16, 2015

(54) METHOD OF MANUFACTURING METAL HYDROXIDES AND METHOD OF MANUFACTURING ITO SPUTTERING TARGET

(71) Applicant: ULVAC, INC., Chigasaki-shi, Kanagawa (JP)

(72) Inventors: Atsushi Fujimaru, Tomisato-shi (JP); Toshifumi Mimura, Tomisato-shi (JP); Yutaka Kadowaki, Tomisato-shi (JP); Katsuhiko Mushiake, Chigasaki-shi (JP)

(73) Assignee: ULVAC, INC., Chigasaki-shi, Kanagawa (JP)

(21) Appl. No.: 14/394,662

(22) PCT Filed: Apr. 16, 2013
(86) PCT No.: PCT/JP2013/002568

§ 371 Date: Oct. 15, 2014

(30) Foreign Application Priority Data
May 31, 2012 (JP) 2012-125364

(51) Int. Cl. H01J 37/34; C25B 1/00

(52) U.S. Cl. CPC H01J 37/3426; C25B 1/00

(57) ABSTRACT

A method of manufacturing metal hydroxides with high mass, and a method of manufacturing an ITO target are provided. A gas diffusion electrode 20 configured such that a hydrophobic gas diffusion layer 20a and a hydrophilic reaction layer 20b are laminated is installed in an electrolytic bath 1 to partition the electrolytic bath. An electrolytic solution S is stored in such a portion of a settling chamber 11 as to face the reaction layer of the partitioned electrolytic bath, and indium 4 is immersed in the electrolytic solution. A voltage is applied between a cathode defined by the gas diffusion electrode and an anode defined by indium. Oxygen is supplied into such a partitioned air chamber 10 as to face the gas diffusion layer to perform electrolysis. Indium hydroxides are thus deposited in the electrolytic solution.

### TECHNICAL FIELD

The present invention relates to a method of manufacturing metal hydroxides and a method of manufacturing an ITO sputtering target, and more specifically, relates to a method of manufacturings metal hydroxides used for producing an ITO target.

### BACKGROUND ART

In flat panel displays such as liquid crystal displays or plasma displays, a transparent conductive film that is an indium tin oxide (hereinafter, referred to as “ITO”) film is used as an electrode. In formation of the ITO film, sputtering devices are widely used in consideration of mass productivity, and the like. As these sorts of sputtering devices, there are ones that apply high-frequency power to an ITO target to form the ITO film (for example, see Patent Document 1).

Patent Document 2 is known to disclose a method of producing such an ITO target. In Patent Document 2, first, an electrolytic solution is stored in an electrolytic bath, indium as an anode and a cathode (for example, iron) are immersed in the electrolytic solution, and a voltage is applied between the both electrodes and electrolysis is performed, whereby indium hydroxides are deposited. Then, the deposited indium hydroxides are collected and baked, and indium oxide powder is obtained. The indium oxide powder is mixed with tin oxide powder at a predetermined ratio. The mixed powder is pulverized, granulated, and pressure-molded, and the pressure-molded product is sintered, whereby the ITO target can be obtained.

Here, indium contained in the ITO target is poor as a resource and an expensive rare metal, and thus it is important how the manufacturing cost of the ITO target is reduced. As a method of reducing the manufacturing cost, reusing the electrolytic solution used in manufacturing the indium hydroxides without disposing the electrolytic solution can be considered. To reuse the electrolytic solution, it is necessary that the used electrolytic solution does not contain impurities, and the composition of the used electrolytic solution has not been changed. To be specific, when ammonium nitrate is used as the electrolytic solution, it is necessary to maintain constant the concentration of nitrate ions and the like in the electrolytic solution.

However, when ammonium nitrate is used as the electrolytic solution, the standard electrode potential (+0.01 V) of a reduction reaction of a nitrate ion (NO₃⁻ +2H⁺+2e⁻→NO₂⁻+H₂O) is higher than the standard electrode potential (−0.83 V) of a reduction reaction of water, and thus in the cathode of the above conventional case, the reduction reaction of the nitrate ions is more easily caused than the reduction reaction of water, and the concentration of the nitrate ions is decreased and the concentration of nitrite ions is increased during electrolysis. Therefore, the composition of the electrolytic solution is changed, and the nitrite ions are contained as impurities in the electrolytic solution after the electrolysis. Such an electrolytic solution cannot be reused and waste liquid treatment is performed. Therefore, the cost of the waste liquid treatment is required, and thus the manufacturing cost cannot be decreased. Moreover, replacement work of the electrolytic solution is required, and mass productivity is significantly impaired.

Further, when the composition of the electrolytic solution is changed, the pH and the temperature of the electrolytic solution become unstable. The particle diameter of the metal hydroxide is subject to effects of the pH or the temperature of the electrolytic solution, and when the pH of the electrolytic solution is low or the temperature of the electrolytic solution is high, the particle diameter becomes large, and it becomes difficult to obtain the metal hydroxides having a uniform desired particle diameter.

### PRIOR ART DOCUMENTS

### Patent Documents

Patent Document 1: JP 2009-138230 A

Patent Document 2: JP 6-171937 A

### SUMMARY OF THE INVENTION

### Problems to be Solved by the Invention

In view of the foregoing, an object of the present invention is to provide a method of manufacturing metal hydroxides with high mass productivity, capable of having a uniform desired particle diameter, and having no need for performing waste liquid treatment of an electrolytic solution, and to provide a method of manufacturing an ITO sputtering target.

### Means of Solving the Problems

In order to solve the above-described problems, a method of manufacturing metal hydroxides according to the present invention includes: installing in an electrolytic bath a gas diffusion electrode configured by laminating a hydrophobic gas diffusion layer and a hydrophilic reaction layer, thereby partitioning the electrolytic bath; storing an electrolytic solution in such a portion of the partitioned electrolytic bath as to face the reaction layer; immersing a metal material or a conductive metal oxide in the electrolytic solution; applying a voltage between a cathode defined by the gas diffusion electrode and an anode defined by the metal material or the conductive metal oxide; supplying oxygen to such a portion of the partitioned electrolytic bath as to face the gas diffusion layer, thereby performing electrolysis to deposit the metal hydroxides in the electrolytic solution.

According to the present invention, an explanation is made of an example in which indium hydroxides are deposited by using indium as a metal material and ammonium nitrate as an electrolytic solution. Indium ions (In³⁺) are eluted from an anode during electrolysis, the eluted indium ions react with hydroxide ions in the electrolytic solution, and indium hydroxides are deposited. At this time, in a gas diffusion electrode of a cathode, oxygen is supplied to a reaction layer through a gas diffusion layer, a gas-liquid interface of the oxygen and the electrolytic solution is caused inside the reaction layer, the oxygen is reduced in the gas-liquid interface, and hydroxide ions are generated (O₂+2H₂O+4e⁻→4OH⁻). The standard electrode potential (+0.40 V) of the reduction reaction of the oxygen is higher than the standard electrode potential (+0.01 V) of the reduction reaction of the nitrate ion, and thus, in the cathode, the reduction reaction of the nitrate ions is rarely caused, and the composition of the electrolytic solution is not changed. Therefore, if the deposited indium hydroxides are collected, the electrolytic solution remaining after the collection can be reused for the next electrolysis, and the waste liquid treatment of the electrolytic solution and the replacement work of the electrolytic solution are not necessary after the electrolysis. Therefore, the manufacturing cost can be decreased, and the high mass productivity can be achieved. Moreover, the hydroxide ions used for synthesis of the indium hydroxides are replenished from the cathode to the electrolytic solution. Therefore, the pH and the temperature of the electrolytic solution during the electrolysis can be stabilized in combination with the unchanged composition of the electrolytic solution, and the metal hydroxides having a uniform desired particle diameter can be obtained. Further, the standard electrode potential (−0.83 V) of the reduction reaction of water is lower than the standard electrode potential of the reduction reaction of the nitrate ion. Therefore, hydrogen is not caused due to the reduction of water in the cathode.

Note that, in the present invention, supplying oxygen to the portion facing the gas diffusion layer includes not only a case of positively supplying an oxygen-containing gas to the portion through a gas supply pipe, but also a case of exposing the gas diffusion layer of the gas diffusion electrode to the atmosphere to supply oxygen to the gas-liquid interface formed on the reaction layer in a steady manner.

The present invention is suitable for the case of using indium as the metal material and ammonium nitrate as the electrolytic solution. The method of manufacturing an ITO sputtering target of the present invention is to manufacture the ITO sputtering target using indium hydroxides obtained by the above-described method of manufacturing metal hydroxides. Accordingly, a high-density ITO sputtering target can be produced.

In the present invention, the gas diffusion layer is preferably configured from hydrophobic carbon and a base material, and the reaction layer is preferably configured from hydrophilic carbon carrying a catalyst, hydrophobic carbon, and a base material.

### BRIEF DESCRIPTION OF THE DRAWINGS

FIG. 1 is a schematic diagram illustrating an electrolytic device used for a method of manufacturing metal hydroxides of an embodiment of the present invention.

FIG. 2 is an exploded perspective view of an electrolytic bath illustrated in FIG. 1.

FIGS. 3(a) and 3(b) are graphs illustrating experimental results of the present invention.

### MODES FOR CARRYING OUT THE INVENTION

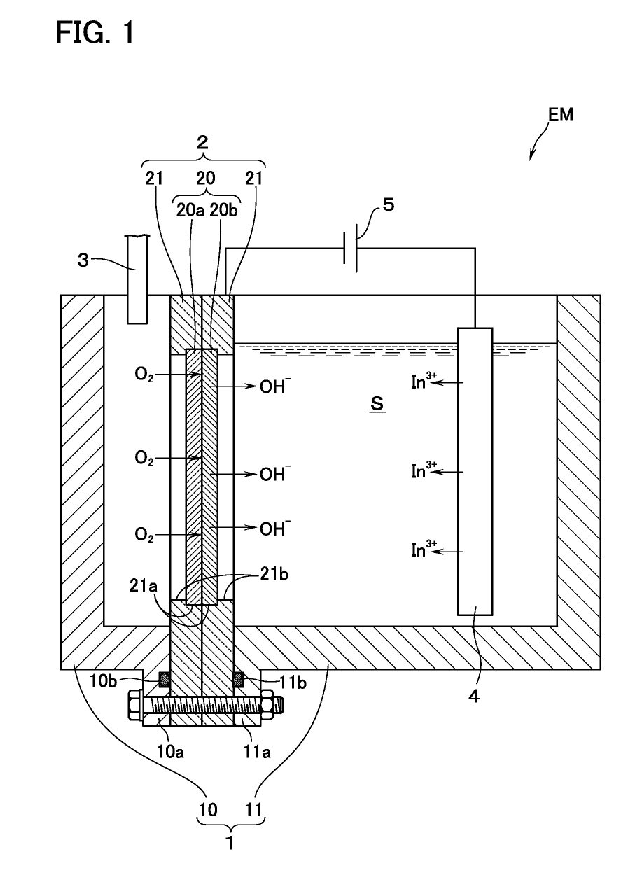

Referring to FIG. 1, an electrolytic device EM is an electrolytic device used in the present embodiment, and the electrolytic device EM includes an electrolytic bath 1. The electrolytic bath 1 is configured from an air chamber 10 and settling chamber 11. These air chamber 10 and settling chamber 11 have open upper surfaces and open one side surface respectively. Flange portions 10a and 11a are formed at peripheries of the respective one side surface. Packing 10b and 11b are fit into recessed grooves formed in the flange portions 10a and 11a, and can seal an electrolytic solution between the packing 10b and 11b and holding plates 21 described below.

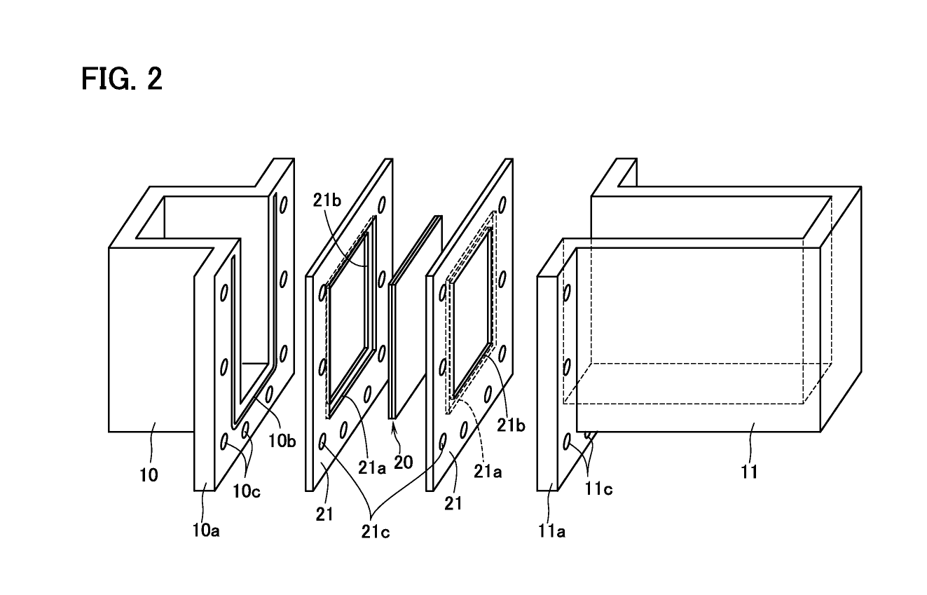

A cathode 2 is provided in the electrolytic bath 1, and the cathode 2 partitions the electrolytic bath 1. The cathode 2 is configured by a gas diffusion electrode 20, and two sheets of holding plates 21 made of titanium that sandwich the gas diffusion electrode 20. The holding plate 21 plays a role of efficiently energizing the gas diffusion electrode 20. The gas diffusion electrode 20 is formed such that a hydrophobic gas diffusion layer 20a and a hydrophilic reaction layer 20b are laminated. As the gas diffusion electrode 20, the gas diffusion layer 20a can be configured by hydrophobic carbon and PTFE (a fluorine-based resin) as a base material, and the reaction layer 20b can be configured by hydrophilic carbon that carries a catalyst made of platinum or silver, hydrophobic carbon, and PTFE as a base material. A recessed portion 21a having an external form that approximately coincides with an outline of the gas diffusion electrode 20 and a depth that is approximately half of the thickness of the gas diffusion electrode 20 is formed in each of the holding plates 21, and the gas diffusion electrode 20 is embedded in the recessed portions 21a. Referring to FIG. 2, through holes 10c, 21c, and 11c respectively formed in the flange portion 10a of the air chamber 10, the holding plates 21, and the flange portion 11a of the settling chamber 11 are positioned, and a bolt is inserted into the through holes 10c, 21c, and 11c and is fastened with a nut, in a state where the gas diffusion electrode 20 is sandwiched by both of the holding plates 21, whereby the gas diffusion electrode 20 is positioned and held inside the electrolytic bath 1. Openings 21b communicating with the recessed portions 21a and slightly smaller than the recessed portions 21a are respectively formed in the holding plates 21. Accordingly, the gas diffusion layer 20a faces an inside the air chamber 10 through the opening 21b, and the reaction layer 20b faces an inside of the settling chamber 11 through the opening 21b. A tip of a gas supply pipe 3 is inserted into the air chamber 10, and can introduce air (an oxygen-containing gas) pressurized into a predetermined pressure into the air chamber 10, and further, can supply the air to the gas diffusion layer 20a of the gas diffusion electrode 20. An electrolytic solution S is stored in the settling chamber 11, and a metal material 4 as the anode is immersed in the electrolytic solution S.

As the metal material 4, at least one type of metal selected from indium, tin, copper, gallium, zinc, aluminum, iron, nickel, manganese, and lithium, or an alloy containing at least one type selected from these metals. As the electrolytic solution S, at least one type selected from ammonium nitrate, ammonium chloride, ammonium sulfate, ammonium acetate, sodium sulfate, sodium chloride, potassium chloride, potassium nitrate, and potassium sulfate. Here, in consideration of points that the amount of impurities (nitrogen) contained in the metal hydroxides to be deposited can be made small, and the impurities can be easily removed by thermal treatment at a relatively low temperature, it is favorable to use ammonium nitrate. The pH and the temperature (the electrolysis temperature) of the electrolytic solution S can be appropriately set such that the metal hydroxides can be efficiently deposited. If the electrolysis temperature is set to the room temperature, temperature control means of the electrolytic solution S is not necessary, and thus it is favorable in terms of the device cost.

The electrolytic device EM further includes a DC power source 5, and can apply a predetermined voltage between the gas diffusion electrode 20 as the cathode and the metal material 4 as the anode. The applied voltage can be appropriately set to have predetermined current density (for example, 2.5 A/dm²). For example, when ammonium nitrate is used as the electrolytic solution S, the applied voltage can be set within a range of 2.5 to 3.0 V. When ammonium chloride or ammonium sulfate is used as the electrolytic solution S, the applied voltage can be set within a range of 1.5 to 2.0 V. Further, when ammonium acetate is used as the electrolytic solution S, the applied voltage can be set within a range of 4.5 to 5.0 V. Hereinafter, a method of manufacturing metal hydroxides of the present embodiment will be described, taking a case as an example, in which the electrolytic device EM is used, ammonium nitrate is used as the electrolytic solution S, indium is used as the metal material 4, and the air is supplied through the gas supply pipe 3 into the air chamber 10 to perform the electrolysis, whereby the indium hydroxides are deposited.

First, as described above, the air chamber 10, the cathode 2, and the settling chamber 11 are assembled using a plurality of bolts, so that the gas diffusion electrode 20 is installed inside the electrolytic bath 1. The electrolytic solution S is stored in the settling chamber 11 partitioned by the gas diffusion electrode 20 (cathode 2), and the indium 4 is immersed in the electrolytic solution S. When a voltage is applied from the power source 5 between the electrodes where the gas diffusion electrode 20 is the cathode and the indium 4 is a positive electrode, indium ions (In³⁺) are eluted from the indium 4 to the electrolytic solution S. These eluted indium ions react with the hydroxide ions in the electrolytic solution S, whereby the indium hydroxides (In(OH)₃) are deposited, and the deposited indium hydroxides are settled in a bottom of the settling chamber 11.

At this time, when the air is introduced through the gas supply pipe 3 into the air chamber 10, oxygen is supplied to the reaction layer 20b through the gas diffusion layer 20a. Accordingly, a gas-liquid interface is formed inside the reaction layer 20b, the reduction reaction of the oxygen is caused in the gas-liquid interface, and hydroxide ions are supplied into the electrolytic solution S. Here, the standard electrode potential of the reduction reaction of the oxygen is higher than the standard electrode potential of the reduction reaction of the nitrate ion, and thus the reduction reaction of the nitrate ions is rarely caused in the cathode. Therefore, the composition of the electrolytic solution (the concentration of the nitrate ions and ammonium ions) is approximately constant, and furthermore, nitrite ions are not contained as impurities. Therefore, if the deposit indium hydroxides are collected, the electrolytic solution remaining after the collection can be reused for the next electrolysis, and the waste liquid treatment of the used electrolytic solution and the replacement work of the electrolytic solution are not necessary. Therefore, the manufacturing cost can be decreased, and high mass productivity can be achieved. Furthermore, while the hydroxide ions are consumed by the synthesis of the indium hydroxides, the consumed hydroxide ions are replenished by the reduction reaction of oxygen. Therefore, the pH and the temperature of the electrolytic solution S during the electrolysis can be stabilized in combination with the unchanged composition, and the indium hydroxides having a uniform desired particle diameter (for example, 100 nm) can be obtained. Therefore, if the above-described obtained indium hydroxides are used as a material, a high-density ITO sputtering target can be produced. In this case, the above-described obtained indium hydroxides are baked to produce indium oxides, the indium oxides are formed into powder and are mixed with tin oxide powder, and the mixed powder is formed and sintered, whereby the ITO sputtering target is manufactured. Here, as conditions of the baking, mixture and formation, sintering, and the like, known conditions can be used, and thus detailed description is omitted.

Note that the standard electrode potential of the reduction reaction of water is lower than the standard electrode potential of the reduction reaction of the nitrate ion. Therefore, hydrogen is not caused due to the reduction of water in the cathode. Further, the nitrite ions are rarely caused, and thus NOx is not caused in the anode. Accordingly, a facility that processes the hydrogen or NOx caused during the electrolysis is unnecessary, and the manufacturing cost can be further decreased.

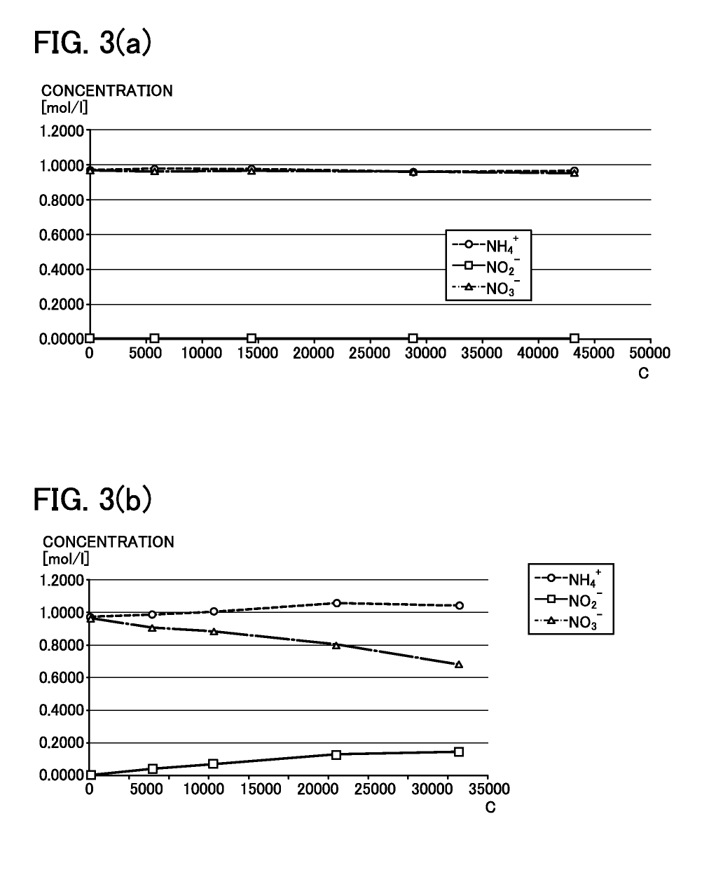

To confirm the above effects, the following experiment was performed using the electrolytic device EM. That is, in the experiment of the invention, a gas diffusion electrode (manufactured by PERMELEC ELECTRODE LID) having the size of 10×10 cm and the thickness of 0.5 mm was used as the cathode, ammonium nitrate having the concentration of 1 mol/l and the pH of 5 was used as the electrolytic solution S, the temperature of the electrolytic solution S was 20° C., a voltage of 2.5 V was applied from the power source 5 (the current density of this time was 2.5 A/dm²), and the electrolysis was performed for five hours and the indium hydroxides were obtained. During the electrolysis, the concentration of the nitrate ions, the nitrite ions, and the ammonium ions contained in the electrolytic solution S were measured. Measurement results are illustrated in FIG. 3(a). Reference letter “C” in the abscissa of FIG. 3(a) represents current (A)×time (sec). According to the experiment of the invention, it has been confirmed that the electrolytic solution after the electrolysis can be reused because the concentration of each ion was approximately constant, the composition of the electrolytic solution S was not changed, and the nitrite ions as impurities were not generated. Further, in the experiment, it has been confirmed that, even if the electrolytic solution S was used in the electrolysis of ten times (five hours at one time), the composition of the electrolytic solution S was not changed. Further, the electrolysis was performed in the same condition as the above condition except that the temperature of the electrolytic solution S was set to 25° C. and 30° C., and the concentration of the above-described ions was measured. As a result, similarly, it has been confirmed that the composition of the electrolytic solution S was not changed.

As a comparative experiment of the above experiment of the invention, the electrolysis was performed using conventional SUS (stainless steel) as the cathode, in place of the gas diffusion electrode, and the same electrolytic solution as the above experiment of the invention, and the indium hydroxides were obtained. Similarly to the above experiment of the invention, the concentration of the ions during the electrolysis was measured, and measurement results are illustrated in FIG. 3(b). In the comparative experiment, it has been confirmed that the reduction reaction of the nitrate ions was caused in the cathode, and the concentration of the nitrate ions was decreased and the concentration of nitrite ions were increased. From this, it has been found out that the electrolytic solution after the electrolysis cannot be reused because the composition of the electrolytic solution S was changed and impurities were contained in the electrolytic solution S.

Note that the present invention is not limited to the above-described embodiment. For example, while in the above-described embodiment, a case of supplying the air through the gas supply pipe 3 into the air chamber 10 has been described, oxygen can just be supplied to the reaction layer 20b of the gas diffusion electrode 20, and a configuration of sending the air into the air chamber 10 by air blowing means may be employed.

Further, in the above-described embodiment, a case of using ammonium nitrate as the electrolytic solution S has been described. However, when the particle diameter of the metal hydroxide is allowed to be large, the above exemplarily described ammonium chloride, ammonium sulfate, ammonium acetate, or the like can be used, for example. In this case, chlorine, sulfur, carbon, or the like is mixed in the deposited metal hydroxides as impurities. To remove the impurities, higher-temperature heat treatment than the case of removing nitrogen needs to be performed, and the particle diameter becomes large during the heat treatment. However, the electrolytic solution can be reused.

Further, in the above-described embodiment, a case of using indium as the metal material 4 has been described. However, in a case where the above exemplarily described metal or alloy that can form the metal hydroxides is used, the present invention can, of course, be applied.

Further, in the above-described embodiment, a case of employing the metal material 4 immersed in the electrolytic solution S as an anode has been described. However, a conductive metal oxide is immersed in the electrolytic solution S, and the immersed conductive metal oxide may be employed as the anode. In this case, a separating film is installed between the anode and the cathode, and desired ions eluted from the conductive metal oxide may be caused to permeate the separating film to the cathode side. Note that, as the conductive metal oxide, ITO, IGZO, or the like can be used.

### EXPLANATION OF REFERENCE NUMERALS

1 Electrolytic bath
2 Cathode
20 Gas diffusion electrode
20a Gas diffusion layer
20b Reaction layer
S Electrolytic solution
4 Indium (anode, metal material)

1. A method of manufacturing metal hydroxides, the method comprising:
installing in an electrolytic bath a gas diffusion electrode configured by laminating a hydrophobic gas diffusion layer and a hydrophilic reaction layer, thereby partitioning the electrolytic bath;
storing an electrolytic solution in such a portion of the partitioned electrolytic bath as to face the reaction layer;
immersing a metal material or a conductive metal oxide in the electrolytic solution;
applying a voltage between a cathode defined by the gas diffusion electrode and an anode defined by the metal material or the conductive metal oxide;
supplying oxygen to such a portion of the partitioned electrolytic bath as to face the gas diffusion layer, thereby performing electrolysis to deposit the metal hydroxides in the electrolytic solution.

2. The method of manufacturing metal hydroxides according to claim 1, wherein indium is used as the metal material, and ammonium nitrate is used as the electrolytic solution.

3. A method of manufacturing an ITO sputtering target, the method comprising:
manufacturing the ITO sputtering target using indium hydroxides manufactured by the method of manufacturing metal hydroxides according to claim 2.
